(19) United States
(12) Patent Application Publication
(10) Pub. No.: US 2011/0055645 A1
(43) Pub. Date: Mar. 3, 2011

(54) SEMICONDUCTOR TEST METHOD, SEMICONDUCTOR TEST APPARATUS, AND COMPUTER READABLE MEDIUM

(75) Inventors: Atsushi INOUE, Fujisawa-shi (JP); Tsunehiro Sato, Yokohama-shi (JP)

(73) Assignee: Kabushiki Kaisha Toshiba, Tokyo (JP)

(21) Appl. No.: 12/873,631

(22) Filed: Sep. 1, 2010

(30) Foreign Application Priority Data
Sep. 2, 2009 (JP) 2009-202858

(51) Int. Cl. G11C 29/08; G06F 11/26

(52) U.S. Cl. 714/718; 714/E11.159

(57) ABSTRACT

A semiconductor test apparatus includes an inputting module, a monitor, a converter, a storage, and a tester. The inputting module inputs addresses for first test, in which the addresses of a plurality of semiconductor memories are arrayed in an arbitrary order. The monitor monitors test time of the first test on each semiconductor memory. The converter sorts the addresses of the semiconductor memories based on the test time in order to convert the address for the first test to addresses for a second test. The storage stores the addresses for the second test. The tester tests each semiconductor device based on the addresses for the second test stored in the storage.

### CROSS REFERENCE TO RELATED APPLICATIONS

This application is based upon and claims the benefit of priority from the prior Japanese Patent Application No. 2009-202858, filed on Sep. 2, 2009, the entire contents of which are incorporated by reference.

### FIELD

Embodiments described herein relate generally to a semiconductor test method and a semiconductor test apparatus.

### BACKGROUND

Conventionally, for example, an IC (Integrated Circuit) tester disclosed in JP-A No. 11-44739 (Kokai) is well known as a semiconductor test apparatus for testing a semiconductor memory device such as a flash memory. In the conventional semiconductor test apparatus, a plurality of tests are simultaneously performed to a plurality of semiconductor memory devices. For example, the flash memories having a good characteristic (short erasing time) and having a poor characteristic (long erasing time) are simultaneously tested in one time, for example, it is a block erasing test of the flash memory. Generally, the test of the flash memory having the good characteristic is ended earlier than the test of the flash memory having the poor characteristic.

However, in the conventional semiconductor test apparatus, the next test can not start until the test of the semiconductor memory device having the poorest characteristic is ended. For example, until the block erasing test is ended for the flash memory having the longest erasing time, the next test of other flash memories whose block erasing tests have been ended can not start.

Accordingly, the test time of the semiconductor memory device having the poorest characteristic becomes a bottleneck, thereby lengthening the whole test time of the semiconductor test. This is a problem common to the general semiconductor test apparatus such as a shared tester and a per site tester.

### BRIEF DESCRIPTION OF THE DRAWINGS

FIG. 1 is a block diagram illustrating a configuration of a semiconductor test apparatus 10 according to the embodiment.

FIG. 2 is a block diagram illustrating a configuration of a tester 102 of FIG. 1.

FIG. 3 is a block diagram illustrating a configuration of a scrambler 103 of FIG. 1.

FIG. 4 is a schematic diagram illustrating a test time of first test on each DUT 30.

FIG. 5 is a block diagram illustrating a configuration of a converter 103b of FIG. 3.

FIGS. 6A to 6D are block diagrams illustrating data structures of pieces of data stored in a buffer 103b-1 and a memory 103c of FIG. 5.

FIG. 7 is a schematic diagram illustrating a test time of a second test on each DUT 30.

FIG. 8 is a flowchart illustrating a procedure of a semiconductor test of the embodiment.

FIG. 9 is a flowchart illustrating a procedure of monitoring (S803) of FIG. 8.

FIG. 10 is a flowchart illustrating a procedure of converting (S804) of FIG. 8.

FIGS. 11A and 11B are schematic diagrams illustrating a comparison example of the embodiment and the related art.

### DETAILED DESCRIPTION

Embodiments will now be explained with reference to the accompanying drawings.

A semiconductor test apparatus includes an inputting module, a monitor, a converter, a storage, and a tester. The inputting module inputs addresses for first test, in which the addresses of a plurality of semiconductor memories are arrayed in an arbitrary order. The monitor monitors test time of the first test on each semiconductor memory. The converter sorts the addresses of the semiconductor memories based on the test time in order to convert the address for the first test to addresses for a second test. The storage stores the addresses for the second test. The tester tests each semiconductor device based on the addresses for the second test stored in the storage.

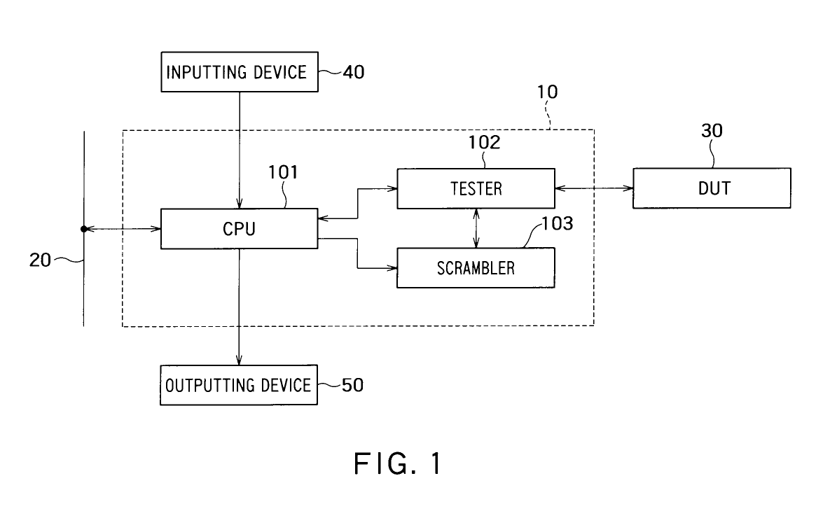

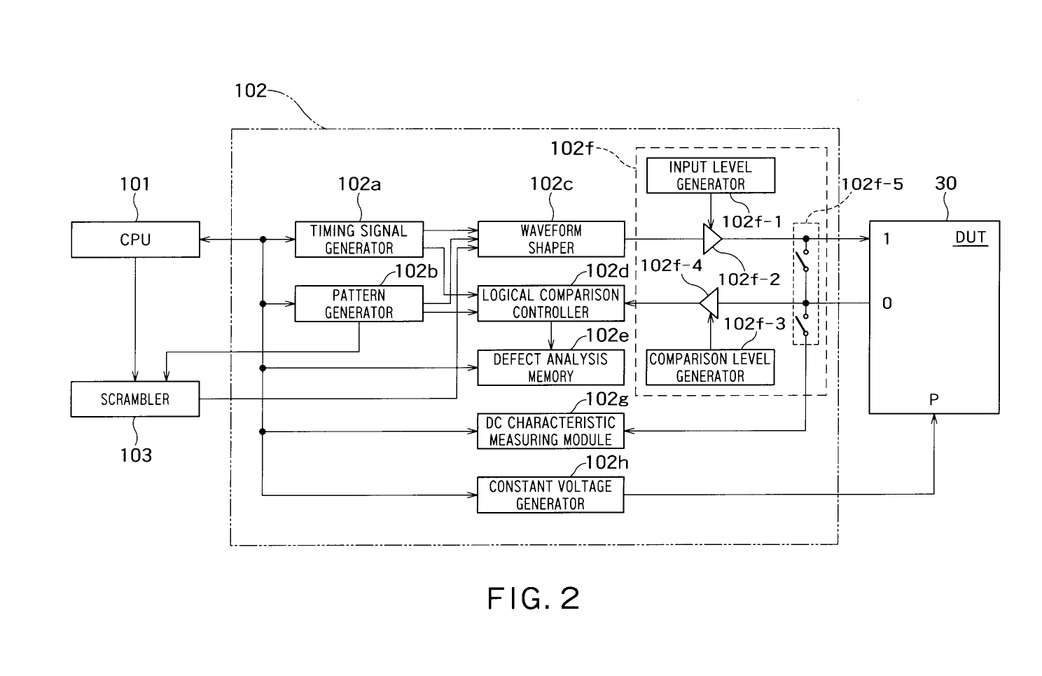

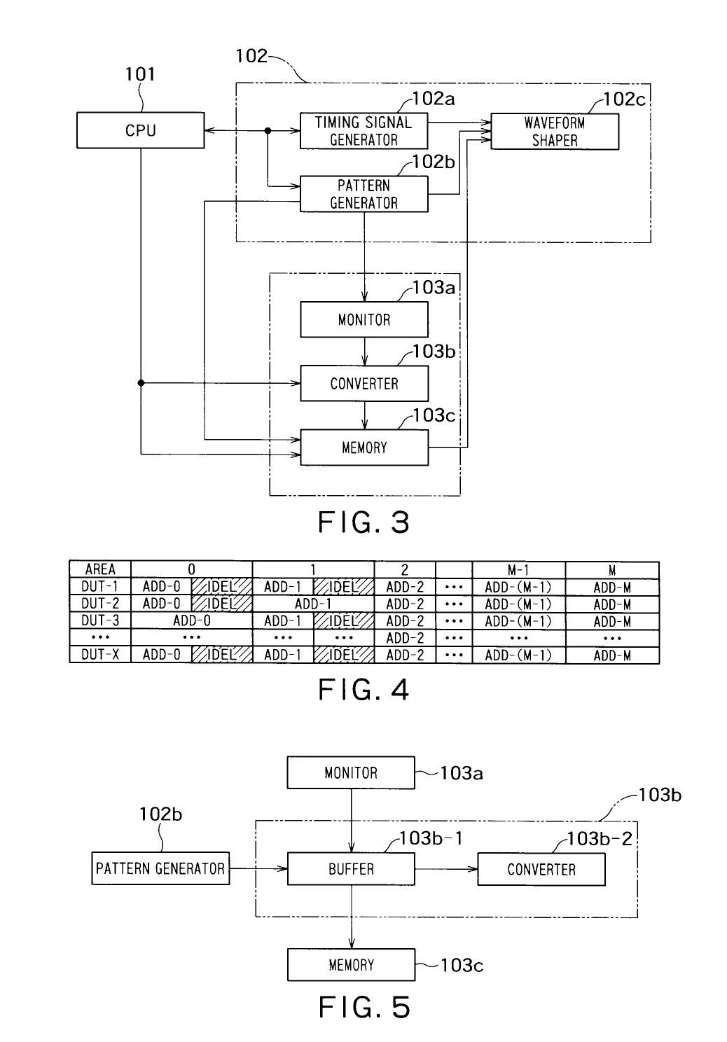

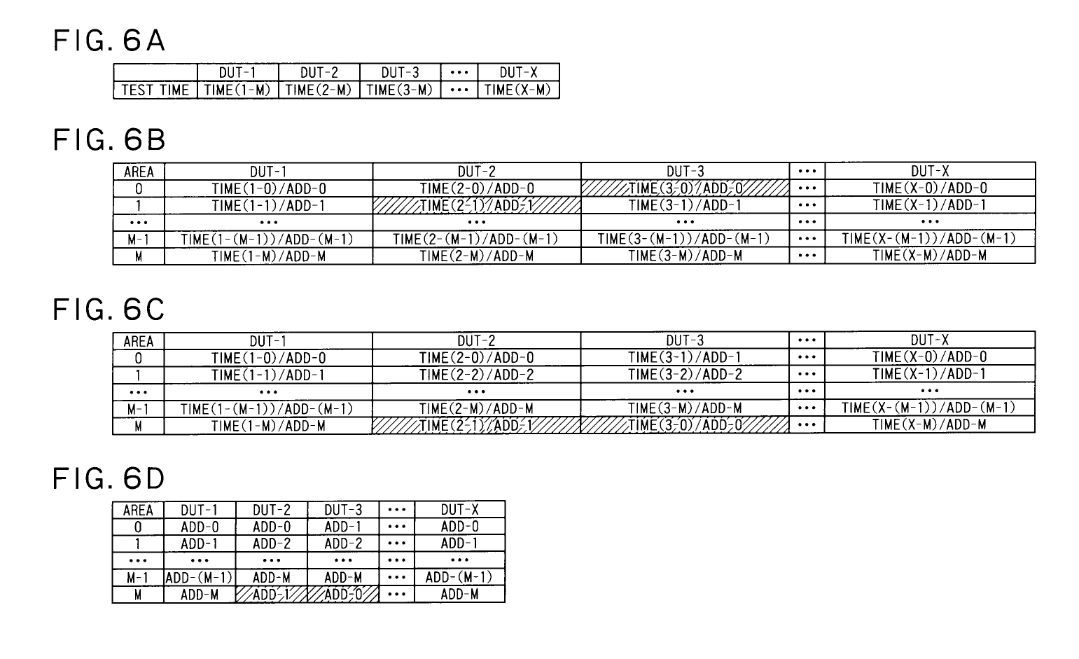

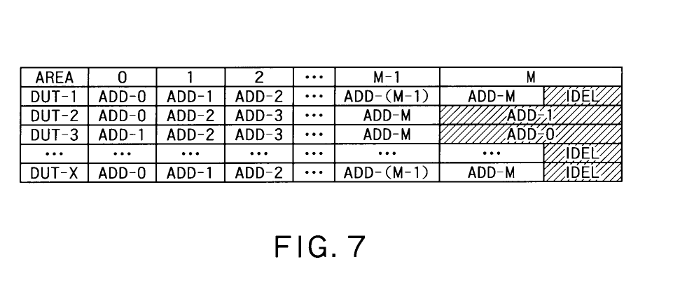

A configuration of a semiconductor test apparatus according to the embodiment will be explained below. FIG. 1 is a block diagram illustrating a configuration of a semiconductor test apparatus 10 according to the embodiment. FIG. 2 is a block diagram illustrating a configuration of a tester 102 of FIG. 1. FIG. 3 is a block diagram illustrating a configuration of a scrambler 103 of FIG. 1. FIG. 4 is a schematic diagram illustrating a test time of first test on each DUT 30. FIG. 5 is a block diagram illustrating a configuration of a converter 103b of FIG. 3. FIGS. 6A to 6D are block diagrams illustrating data structures of pieces of data stored in a buffer 103b-1 and a memory 103c of FIG. 5. FIG. 7 is a schematic diagram illustrating a test time of a second test on each DUT 30.

Referring to FIG. 1, the semiconductor test apparatus 10 includes a CPU (Central Processing Unit) 101, a tester 102, and a scrambler 103. The CPU 101 is connected to the tester 102, the scrambler 103, a communication line 20, an inputting device 40, and an outputting device 50. The tester 102 is connected to the CPU 101, the scrambler 103, and a plurality of devices to be tested (hereinafter referred to as “DUT (Device Under Test)”) 30. The scrambler 103 is connected to the CPU 101 and the tester 102. For example, each DUT 30 is a semiconductor memory device such as a flash memory, the communication line 20 is a LAN (Local Area Network), the inputting device 40 is a keyboard, and the outputting device 50 is a display.

As illustrated in FIG. 1, the CPU 101 realizes a module as an accepting module that accepts a parameter fed by a user using the inputting device 40, a controller that controls the tester 102 and the scrambler 103 so as to test each DUT 30, an output module that outputs the test result of each DUT 30 to the outputting device 50, and a communication module that transmits and receives various pieces of data to and from an external device (not illustrated) through the communication line 20.

The user feeds parameters for test of each DUT 30 to the semiconductor test apparatus 10 using the inputting device 40. The parameters include addresses for test (hereinafter referred to as “addresses for first test”) in which addresses of the DUTs 30 are arrayed in the arbitrary order, expected value pattern data used to make a pass/fail determination of an output signal (hereinafter referred to as “output pattern data”) of each DUT 30, setting of an operation pin of each DUT 30, a command to each DUT 30, and the address of each DUT 30. The semiconductor test apparatus 10 tests each DUT 30 based on the parameters fed by the user, and outputs the test result to the outputting device 50. The user confirms whether each DUT 30 is passed or failed from the test result output from the outputting device 50.

Referring to FIG. 2, the tester 102 includes a timing signal generator 102a, a pattern generator 102b, a waveform shaper 102c, a logical comparison controller 102d, pin electronics 102f, a defect analysis memory 102e, a DC (Direct Current) characteristic measuring module 102g, and a constant voltage generator for DUT power 102h.

As illustrated in FIG. 2, the CPU 101 outputs a control signal to the timing signal generator 102a, the pattern generator 102b, the defect analysis memory 102e, the DC characteristic measuring module 102g, and the constant voltage generator for DUT power 102h. The control signal is used to operate the timing signal generator 102a, the scrambler 103, the defect analysis memory 102e, the DC characteristic measuring module 102g, and the constant voltage generator for DUT power 102h. The CPU 101 outputs a clear signal to the scrambler 103. The clear signal is used to initialize a monitor 103a of the scrambler 103.

As illustrated in FIG. 2, the timing signal generator 102a generates a main clock signal indicating a clock frequency used in the test, a driver timing signal indicating a rising edge and a trailing edge of an input signal (hereinafter referred to as “input pattern data”) to be applied to each DUT 30, and a switching timing signal used to switch input and output of each DUT 30, and outputs the main clock signal, the driver timing signal, and the switching timing signal to the waveform shaper 102c. The timing signal generator 102a generates a comparator timing signal in order to compare the output pattern data and the expected value pattern data, and outputs the generated comparator timing signal to the logical comparison controller 102d. That is, the timing signal generator 102a generates a signal (timing signal) concerning time and outputs the generated signal to the waveform shaper 102c and the logical comparison controller 102d.

As illustrated in FIG. 2, using an arithmetic device (not illustrated) formed by hardware, the pattern generator 102b generates the input pattern data corresponding to the address for first test in real time during the test of each DUT 30 and outputs the generated input pattern data to the waveform shaper 102c and the scrambler 103. That is, the input pattern data is data that is used to test each DUT 30 based on the address for first test fed by the user. The pattern generator 102b generates a timer resetting signal used to initialize a timer of the monitor 103a of the scrambler 103 of FIG. 3, a monitoring start signal used to cause the monitor 103a to start processing, a monitoring stop signal used to cause the monitor 103a to stop the processing, and a test end signal used to end the test. The pattern generator 102b outputs the timer resetting signal, the monitoring start signal, the monitoring stop signal, and the test end signal to the scrambler 103. The timer resetting signal is used to initialize the scrambler 103. The monitoring start signal is used to provide a command to start the processing to the scrambler 103. The monitoring stop signal is used to provide a command to stop the processing to the scrambler 103. The test end signal is used to cause the scrambler 103 to end the test. The pattern generator 102b outputs the expected value pattern data used to make the pass/fail determination of each DUT 30 to the logical comparison controller 102d. For example, the pattern generator 102b is an algorithmic pattern generator. That is, the pattern generator 102b generates the signal (input pattern data) concerning a signal level and outputs the generated signal to the scrambler 103.

As illustrated in FIG. 2, the waveform shaper 102c combines the input pattern data output from the pattern generator 102b and the driver timing signal output from the timing signal generator 102a, outputs the combination result to a driver 102f-2 of the pin electronics 102f to shape a waveform of the signal to be applied to each DUT 30. For example, assuming that the input pattern is {L,H,L} (H: high and L: low) while the driver timing signal is {10 ns, 20 ns, 10 ns}, the shaped waveform becomes a digital signal of “0110” (1: high and 0: low). That is, the waveform shaper 102c combines the input pattern data and the driver timing signal to shape the waveform such that the waveform includes signals having a high-level period and a low-level period.

As illustrated in FIG. 2, the logical comparison controller 102d logically compares the output pattern data output from each DUT 30 and the expected value pattern data output from the pattern generator 102b in timing of the timing signal output from the timing signal generator 102a, and makes the pass/fail determination of each DUT 30 based on the logical comparison result.

A read operation will be explained as an operation example of the logical comparison controller 102d. First, the user feeds the parameters (such as the pin setting of the read operation of each DUT 30, the command to each DUT 30, and a read address). Each DUT 30 outputs the output pattern data corresponding to the read address. The output pattern data is data in which a data output pin becomes the high level or the low level. The logical comparison controller 102d receives the expected value pattern data output from the pattern generator 102b, logically compares the expected value pattern data corresponding to data written in each DUT 30 and the output pattern data corresponding to data read from each DUT 30 in timing of the timing signal output from the timing signal generator 102a, and makes the pass/fail determination of each DUT 30 based on the logical comparison result. For example, the pass/fail determination result is “pass” when the output pattern data and the expected value pattern data are matched with each other, and the pass/fail determination result is “fail” when the output pattern data and the expected value pattern data are not matched with each other.

As illustrated in FIG. 2, information indicating a defect generation status such as the address and data at which the defect determination is made can be stored in the defect analysis memory 102e. The logical comparison controller 102d writes the information indicating the defect generation status in the defect analysis memory 102e. The information indicating the defect generation status is used for defect analysis and obtaining information for relieving a defective bit.

As illustrated in FIG. 2, the pin electronics 102f includes an input level generator 102f-1, a driver 102f-2, a comparison level generator 102f-3, a comparator 102f-4, and a relay switch 102f-5. The driver 102f-1 generates high-level and low-level voltages to be input to each DUT 30. The driver 102f-2 applies the voltage (high level or low level) necessary for the waveform (digital signal) shaped by the waveform shaper 102c. The comparison level generator 102f-3 generates a voltage in order to make a determination of the level (high level or low level) with respect to the output of each DUT 30. The comparator 102f-4 converts the output waveform of each DUT 30 into the digital signal. The relay switch 102f-5 is connected to a driver 102f-2, a comparator 102f-4, a DC characteristic measuring module 102g.

As illustrated in FIG. 2, the DC characteristic measuring module 102g performs a DC characteristic test of each DUT 30. For example, the DC characteristic measuring module 102g has operation modes. The operation modes include two modes, that is, a current applying voltage measuring mode in which a constant current is passed through each DUT 30 to measure a voltage and a voltage applying current measuring mode in which a constant voltage is passed through each DUT 30 to measure a current.

As illustrated in FIG. 2, the constant voltage generator for DUT power 102h generates the constant voltage for power of each DUT 30 and applies the generated constant voltage for power supply to a power terminal P of each DUT 30.

Referring to FIG. 3, the scrambler 103 includes a monitor 103a, a converter 103b, and a memory 103c.

As illustrated in FIG. 3, using the input pattern data output from the pattern generator 102b, the monitor 103a monitors the test time of each DUT 30 to output the monitoring result to converter 103b. That is, the monitor 103a monitors the test time of the first test on each DUT 30.

As illustrated in FIG. 4, in each DUT 30 (DUT-1 to DUT-X) (X: identification number of DUT 30), the monitoring result of the monitor 103a indicates a test area (AREA-0 to AREA-M) (M: identification number of test area) and the address (ADD-0 to ADD-M) and redundant time (IDEL) of each test area. The redundant time indicates a standby time (that is, wasted time) until another DUT test is ended for the identical test area. FIG. 4 illustrates the generation of the redundant time (IDEL) in the tests of DUT-1, DUT-3, and DUT-X due to a poor address (ADD-1) characteristic of the DUT-2 in the test area (AREA-1) and the generation of the redundant time (IDEL) in the tests of DUT-1, DUT-2, and DUT-X due to a poor address (ADD-0) characteristic of the DUT-3 in the test area (AREA-0).

As illustrated in FIG. 3, the converter 103b sorts the addresses of the DUTs 30 based on the monitoring result output from the monitor 103a, converts the addresses for first test into addresses (hereinafter referred to as “addresses for second test”) having an array different from that of the addresses for first test such that the whole test time is shortened compared with the case of the first test (that is, the first test on all the DUTs 30), and writes the converted addresses for second test in the memory 103c.

Referring to FIG. 5, the converter 103b includes a buffer 103b-1 and a converter 103b-2.

The monitoring result output from the monitor 103a can be stored in the buffer 103b-1 of FIG. 5. FIG. 6A illustrates the monitoring result output from the monitor 103a. As illustrated in FIG. 6A, the monitoring result includes a test time (TIME (X-M)) in each test area (AREA-M) of the DUT 30. In FIG. 6A, “TIME (X-M)/ADD-M” indicates that the test time of the address (ADD-M) of the DUT-X is “TIME (X-M)” in the test area (AREA-M).

FIG. 6B illustrates the monitoring result stored in the buffer 103b-1. As illustrated in FIG. 6B, the monitoring result is written in the buffer 103b-1 for all the test areas (AREA-0 to AREA-M) of each DUT 30. The monitoring result includes a combination of the test times (TIME (X-M)) of each DUT 30 and the pre-sorting addresses (ADD-0 to ADD-M) corresponding to the test times. FIG. 6B illustrates the poor characteristics of the test area (AREA-1) of the DUT-2 and the test area (AREA-0) of the DUT-3.

As illustrated in FIG. 5, the converter 103b-2 sorts the addresses of each DUT 30 to write the sorting result in the buffer 103b-1 such that all the test areas (AREA-0 to AREA-M) of each DUT 30 are arrayed in an ascending order or a descending order with respect to the test time in the monitoring result stored in the buffer 103b-1.

The sorting result written by the converter 103b-2 can also be stored in the buffer 103b-1 of FIG. 5. FIG. 6C illustrates a relationship between the test time and address of each DUT 30 after the addresses are sorted by the converter 103b-2. As illustrated in FIG. 6C, the combinations of the test times (TIME (X-M)) of each DUT 30 and the post-sorting addresses (ADD-0 to ADD-M) corresponding to the test times are written in the buffer 103b-1 with respect to all the test areas (AREA-0 to AREA-M) of each DUT 30. In FIG. 6C, the addresses of each DUT 30 are sorted such that the poor-characteristic address (ADD-1) of the DUT-2 is tested after the good characteristic addresses (ADD-0, and ADD-2 to ADD-M) and such that the poor-characteristic address (ADD-0) of the DUT-3 after the good-characteristic addresses (ADD-1 to ADD-M).

When the sorting results for all the test areas (AREA-0 to AREA-M) are stored in the buffer 103b-1, only the address portions (ADD-0 to ADD-M) in the sorting results are transferred to the memory 103c. The converter 103c-2 converts the address portions transferred to the memory 103c into the addresses for second test.

As illustrated in FIG. 3, the address portions transferred from the buffer 103b-1 and the addresses for second test converted by the converter 103b can be stored in the memory 103c. FIG. 6D illustrates a data structure of the addresses for second test. As illustrated in FIG. 6D, the addresses (ADD-0 to ADD-M) of each DUT 30 are stored in the memory 103c in the order of the post-converting test areas (AREA-0 to AREA-M) in each of the DUTs 30 (DTU-1 to DUT-X). In FIG. 6D, the DUT-1 is tested in the order of addresses (ADD-0, ADD-1, . . . , ADD-(M-1), ADD-M), the DUT-2 is tested in the order of addresses (ADD-0, ADD-2, . . . , ADD-M, ADD-1), the DUT-3 is tested in the order of addresses (ADD-1, ADD-2, . . . , ADD-M, ADD-0), and the DUT-X is tested in the order of addresses (ADD-0, ADD-1, . . . , ADD-(M-1), ADD-M). The addresses for second test stored in the memory 103c are transferred to the waveform shaper 102c.

That is, the scrambler 103 realizes a test time monitoring module and an address scrambling module. The test time monitoring module monitors the test times of the tests of the DUTs 30. The address scrambling module scrambles the pieces of input pattern data output from the pattern generator 102b into the address array of each DUT 30, and feeds back the scrambled address array of each DUT 30 to the waveform shaper 102c.

As illustrated in FIG. 6D, in the test (hereinafter referred to as “second test”) of each DUT 30 based on the addresses for second test converted by the converter 103b, the test areas are arrayed in the order different from that of the first test. As a result, as illustrated in FIGS. 4 and 7, the whole redundant time (IDEL) is shortened compared with the case of the first tests to all the DUTs 30. Accordingly, the whole test time of the semiconductor test can be also shortened.

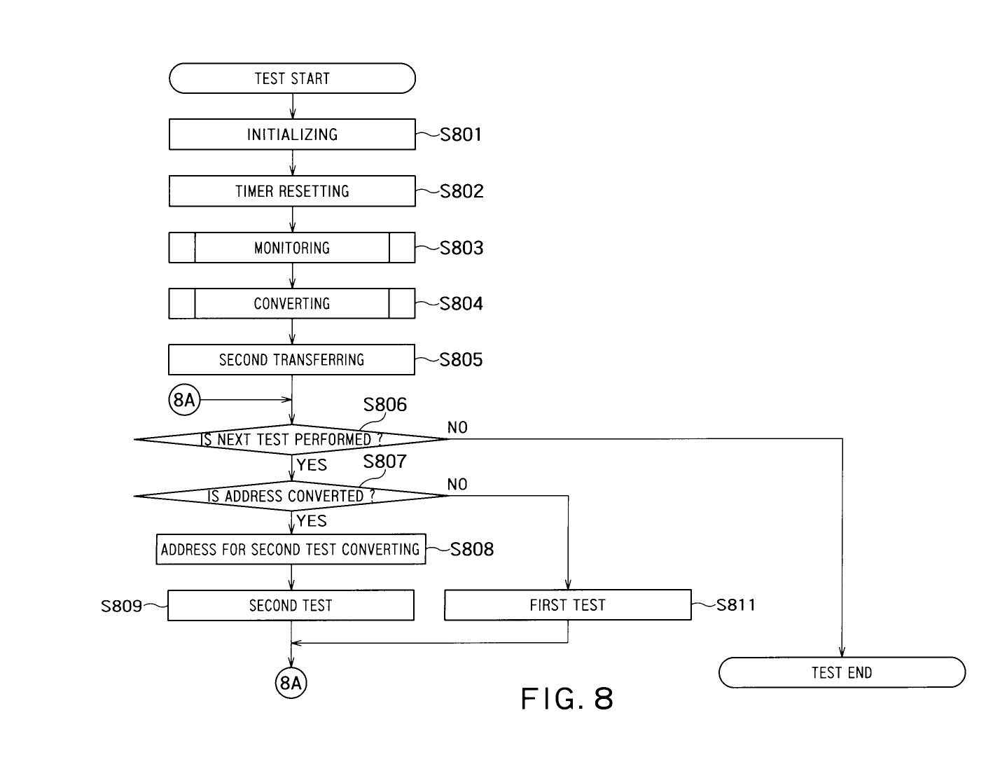

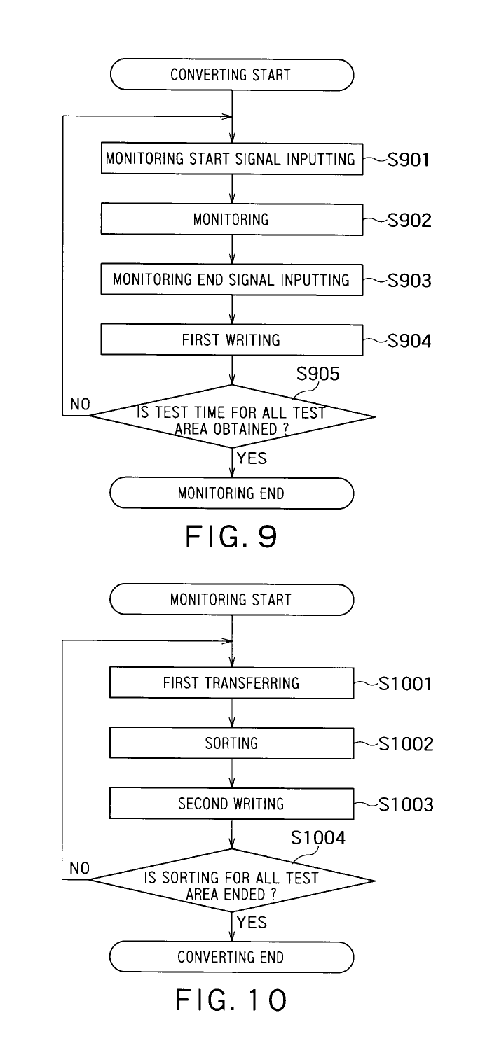

Operations of the semiconductor test apparatus 10 of the embodiment will be explained below. FIG. 8 is a flowchart illustrating a procedure of a semiconductor test of the embodiment. FIG. 9 is a flowchart illustrating a procedure of monitoring (S803) of FIG. 8. FIG. 10 is a flowchart illustrating a procedure of converting (S804) of FIG. 8.

<FIG. 8: Initializing (S801)>

The clear signal output from the CPU 101 is input to the buffer 103b-1 and the memory 103c. As a result, the pieces of data (pieces of data used in the previous test) stored in the buffer 103b-1 and memory 103c are cleared. That is, the buffer 103b-1 and the memory 103c are initialized.

<FIG. 8: Timer Resetting (S802)>

The timer resetting signal output from the pattern generator 102b is input to the scrambler 103. As a result, the value of the timer in the monitor 103a of the scrambler 103 is reset. That is, the monitor 103a of the scrambler 103 is initialized.

<FIG. 8: Monitoring (S803)>

A procedure of the monitoring is illustrated in FIG. 9.

<FIG. 9: Monitoring Start Signal Inputting (S901)>

The monitoring start signal output from the pattern generator 102b is input to the scrambler 103 in order to start the monitoring of the test time of a predetermined test area (AREA-M). As a result, the timer of the monitor 103a of the scrambler 103 starts measuring the test time of each DUT 30.

<FIG. 9: Monitoring (S902)>

The timer of the monitor 103a of the scrambler 103 measures the test time of each DUT 30. As a result, the test time is obtained in each DUT 30 in the case of the first test on the test area (AREA-M) of each DUT 30 (see FIG. 6A).

<FIG. 9: Monitoring End Signal Inputting (S903)>

The monitoring stop signal output from the pattern generator 102b is input to the scrambler 103. Thereby, the monitoring of the test time is ended at the same time as the first test of the test area (AREA-M) is ended,

<FIG. 9: First Writing (S904)>

The obtained test time of each DUT 30 is written in the buffer 103b-1. That is, the test time in the case of the first test in each of the test areas (AREA-0 to AREA-M) of each DUT 30 is stored in the buffer 103b-1 (see FIG. 6B).

<FIG. 9: S905>

When the test times are obtained for all the test areas (YES in S905), the monitoring (S803) is ended, and the flow goes to converting (S804). When the test area where the test time is not obtained remains (NO in S905), the flow returns to monitoring start signal inputting (S901).

<FIG. 8: Converting (S804)>

A procedure of the converting is illustrated in FIG. 10.

<FIG. 10: First Transferring (S1001)>

The data stored in the buffer 103b-1 is transferred to the converter 103b-2. The buffer 103b-1 is initialized after the data stored in the buffer 103b-1 has been transferred.

<FIG. 10: Sorting (S1002)>

For the data transferred to the converter 103b-2, the addresses (ADD-0 to ADD-M) of each DUT 30 are sorted so as to be arrayed in the ascending order or descending order with respect to the test time (see FIG. 6C).

<FIG. 10: Second Writing (S1003)>

The sorting result of sorting (S1002), that is, the addresses (ADD-0 to ADD-M) of each DUT 30 are arrayed in the ascending order or descending order with respect to the test time, are written in the buffer 103b-1.

<FIG. 10: S1004>

When converting is ended for all the test areas (YES in S1004), the test end signal output from the pattern generator 102b is input to the scrambler 103 to end converting (S804), and the flow goes to second transferring (S805). When the test area where sorting (S1002) is not ended remains (NO in S1004), the flow goes to first transferring (S1001).

<FIG. 8: Second Transferring (S805)>

The data stored in the buffer 103b-1, that is, the addresses (ADD-0 to ADD-M) of each DUT 30 are arrayed in the ascending order or descending order with respect to the test time, are transferred to the memory 103c.

<FIG. 8: S806>

When the next test is performed (YES in S806), the flow goes to S807. When the next test is not performed (NO in S806), the semiconductor test of the embodiment is ended.

<FIG. 8: S807>

When the converting result of the previous test is used in the next test (YES in S807), the flow goes to the second test (S809). When the converting result of the previous test is not used in the next test (NO in S807), the flow goes to the first test (S811). The CPU 101 refers to a flag set on a test program, thereby performing the procedure in S807.

<FIG. 8: Address for Second Test Converting (S808)>

The address information output from the pattern generator 102b and the data (addresses (ADD-0 to ADD-M) of each DUT 30 arrayed in the ascending order or descending order with respect to the test time) stored in the memory 103c are converted into the addresses for second test in each DUT 30 based on the flag set on the test program (see FIG. 6D).

<FIG. 8: Second Test (S809)>

The addresses for second test that are of the converting result of address for second test converting (S808) are input to the waveform shaper 102c, the input pattern data and the timing signal are combined based on the addresses for second test, and the combination result is input to the driver 102f-2 of the pin electronics 102f. Then the second test of each DUT 30 is performed based on the addresses for second test converted by the converter 103b. The flow returns to the processing in S806 after the second test (S809).

<FIG. 8: First Test (S811)>

The addresses for first test fed by the user using the inputting device 40 are input to the waveform shaper 102c, the input pattern data and the timing signal are combined based on the addresses for first test, and the combination result is input to the driver 102f-2 of the pin electronics 102f. Then the first test of each DUT 30 is performed based on the addresses for first test fed by the user. The flow returns to the processing in S806 after the first test (S811).

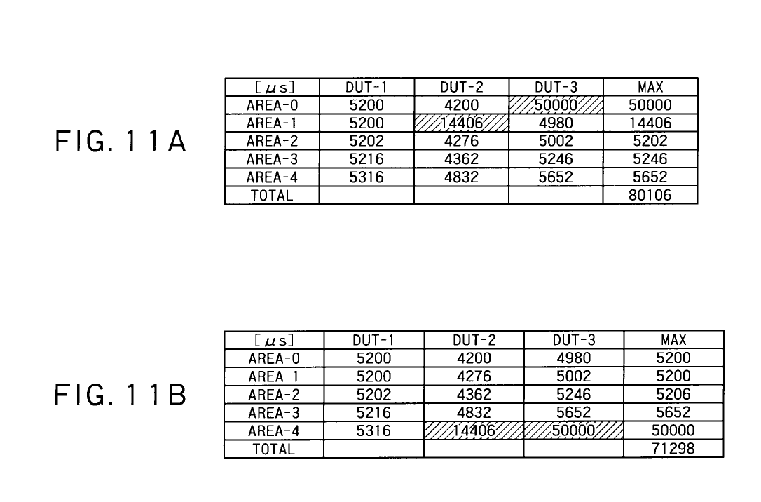

The embodiment and a comparative example of the related art will be explained. FIG. 11 is a schematic diagram illustrating a comparison example of the embodiment and the related art. FIG. 11 illustrates the case of the three (X=3) DUTs 30 and the four (M=4) test areas.

As illustrated in FIG. 11A, in the related art, because the test time (14406 μs) of the DUT-2 in the test area (AREA-1) and the test time (50000 μs) of the DUT-3 in the test area (AREA-0) are larger than those of other test areas, the first tests performed to the test area (AREA-1) and the test area (AREA-0) become bottlenecks (see numerical values in black-out portions of FIG. 11A). In each test area, because the maximum value of the test time of each DUT 30 becomes the test time of the test area, the test time of the test area (AREA-0) is 50000 μs, and the test time of the test area (AREA-1) is 14406 μs. As a result, the total of test times becomes 80106 μs.

On the other hand, as illustrated in FIG. 11B, in the embodiment, because the test (test time of 14406 μs) of the poor-characteristic DUT-2 and the test (test time of 50000 μs) of the poor-characteristic DUT-3 are concentrated in the test area (AREA-4) (see numerical values in black-out portions of FIG. 11B), the total of test times becomes 71298 μs that is shorter than that of FIG. 11A.

According to the embodiment, the addresses of each semiconductor memory device are sorted based on the test time, the addresses for first test are converted into the addresses for second test, and the test is performed based on the addresses for second test. Thereby, the test time of the semiconductor test can be shortened.

In the embodiment, a degree in which the test time is shortened depends on the characteristic of each DUT 30.

In the embodiment, in monitoring end signal inputting (S903) of FIG. 9, the monitoring stop signal output from the pattern generator 102b is input to the scrambler 103. Alternatively, the logical comparison controller 102d may be configured to output the pass signal to the scrambler 103, and the scrambler 103 may be configured to end the monitoring of the test time when the pass signal is input to the scrambler 103.

In the embodiment, the converter 103 sorts addresses after all the monitoring results have been stored in the buffer 103b-1. Alternatively, the converter 103 may sort addresses each time the monitoring result is stored in the buffer 103b-1.

At least a portion of a semiconductor test apparatus according to the above-described embodiments may be composed of hardware or software. When at least a portion of the semiconductor test apparatus is composed of software, a program for executing at least some functions of the semiconductor test apparatus may be stored in a recording medium, such as a flexible disk or a CD-ROM, and a computer may read and execute the program. The recording medium is not limited to a removable recording medium, such as a magnetic disk or an optical disk, but it may be a fixed recording medium, such as a hard disk or a memory.

In addition, the program for executing at least some functions of the semiconductor test apparatus according to the above-described embodiment may be distributed through a communication line (which includes wireless communication) such as the Internet. In addition, the program may be encoded, modulated, or compressed and then distributed by wired communication or wireless communication such as the Internet. Alternatively, the program may be stored in a recording medium, and the recording medium having the program stored therein may be distributed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor test method comprising:
inputting addresses for first test, in which the addresses of a plurality of semiconductor memories are arrayed in an arbitrary order;
monitoring test time of the first test on each semiconductor memory;
converting the address for the first test to addresses for a second test by sorting the addresses of the semiconductor memories based on the test time; and
testing each semiconductor device based on the addresses for the second test.

2. The method of claim 1, wherein in converting the address for the first test, the addresses for the first test are converted to the addresses for the second test in such a manner that a whole test time in the case of the second test is shorter than the whole test time in the case of the first test.

3. The method of claim 2, wherein in testing each semiconductor device, the first test is performed before converting the address for the first test, the second test is performed after converting the address for the first test.

4. The method of claim 2, wherein in converting the address for the first test, the addresses for the first test are converted to the addresses for the second test in such a manner that the addresses of each semiconductor memory are arrayed in the ascending order or descending order with respect to the test time.

5. The method of claim 3, wherein in testing each semiconductor device, the first test is performed before converting the address for the first test, the second test is performed after converting the address for the first test.

6. A semiconductor test apparatus comprising:
an inputting module configured to input addresses for first test, in which the addresses of a plurality of semiconductor memories are arrayed in an arbitrary order;
a monitor configured to monitor test time of the first test on each semiconductor memory;
a converter configured to sort the addresses of the semiconductor memories based on the test time in order to convert the address for the first test to addresses for a second test;
a storage configured to store the addresses for the second test; and
a tester configured to test each semiconductor device based on the addresses for the second test stored in the storage.

7. The apparatus of claim 6, wherein the converter converts the addresses for the first test to the addresses for the second test in such a manner that a whole test time in the case of the second test is shorter than the whole test time in the case of the first test.

8. The apparatus of claim 7, wherein the tester performs the first test before the addresses for the first test are converted to the addresses for the second test and performs the second test after the addresses for the first test are converted to the addresses for the second test.

9. The apparatus of claim 7, wherein the converter converts the addresses for the first test to the addresses for the second test in such a manner that the addresses of each semiconductor memory are arrayed in the ascending order or descending order with respect to the test time.

10. The apparatus of claim 9, wherein the tester performs the first test before the addresses for the first test are converted to the addresses for the second test and performs the second test after the addresses for the first test are converted to the addresses for the second test.

11. A computer readable medium comprising computer program code for performing a semiconductor test, the computer program code comprising:
inputting addresses for first test, in which the addresses of a plurality of semiconductor memories are arrayed in an arbitrary order;
monitoring test time of the first test on each semiconductor memory;
converting the address for the first test to addresses for a second test by sorting the addresses of the semiconductor memories based on the test time; and
testing each semiconductor device based on the addresses for the second test.

12. The medium of claim 11, wherein in converting the address for the first test, the addresses for the first test are converted to the addresses for the second test in such a manner that a whole test time in the case of the second test is shorter than the whole test time in the case of the first test.

13. The medium of claim 12, wherein in testing each semiconductor device, the first test is performed before converting the address for the first test, the second test is performed after converting the address for the first test.

14. The medium of claim 12, wherein in converting the address for the first test, the addresses for the first test are converted to the addresses for the second test in such a manner that the addresses of each semiconductor memory are arrayed in the ascending order or descending order with respect to the test time.

15. The medium of claim 13, wherein in testing each semiconductor device, the first test is performed before converting the address for the first test, the second test is performed after converting the address for the first test.
